(19) United States
(12) Patent Application Publication
(10) Pub. No.: US 2002/0072217 A1
(43) Pub. Date: Jun. 13, 2002

(54) Method for improving contact reliability in semiconductor devices

(75) Inventors: Uway Tseng, Taichung (TW); Kent Kuohua Chang, Taipei (TW); Hung-Yu Chiu, Hsinchu (TW); Chi-Yuan Chin, Taipei (TW)

Correspondence Address: LOWE HAUPTMAN GOPSTEIN GILMAN & BERNER, LLP, Suite 310, 1700 Diagonal Road, Alexandria, VA, 22314, US

(73) Assignee: MACRONIX INTERNATIONAL CO., LTD.

(21) Appl. No.: 09/734,896

(22) Filed: Dec. 13, 2000

(51) Int. Cl. H01L 21/4763

(52) U.S. Cl. 438/620

(57) ABSTRACT

The method of forming a plurality of contact holes on a semiconductor substrate using multiple-step etching process is disclosed herein. A semiconductor substrate is provided having a plurality of semiconductor devices and a plurality of isolation regions formed thereon. A silicon oxide layer is formed on the plurality of semiconductor devices, the plurality of isolation regions, and the semiconductor substrate. An etching stop layer is formed on the silicon oxide layer followed by depositing an interlevel dielectric layer. A photoresist layer is pattern on the interlevel dielectric layer to define contact regions. A first etching process is performed to create a plurality of contact holes in the interlevel dielectric layer until exposing portions of the etching stop layer. A second etching process is performed to create the plurality of contact holes through the etching stop layer. A third etching process is then performed to create the plurality of contact holes through the silicon oxide layer, exposing portions of the active regions of the plurality of semiconductor devices. The pattern photoresist layer is removed.

### BACKGROUND OF THE INVENTION

1. Field of the Invention

The present invention relates to a method for forming a contact structure, and more specifically to a method for forming a contact structure with improving contact reliability using multiple-step etching process in semiconductor devices.

2. Description of the Prior Art

The semiconductor industry is continually striving to reduce the processing cost of a specific semiconductor chip, by reducing the size of the chip, while still maintaining, or increasing the device density of that specific semiconductor chip. The attainment of additional chips, from a specific size starting semiconductor substrate, reduces the processing cost of a specific chip. The attainment of smaller semiconductor chips has been in part a result of micro-miniaturization, or the ability to fabricate semiconductor chips using sub-micron features. Micro-miniaturization has been accomplished via advancements in specific semiconductor fabrication procedures, such as photolithography and reactive ion etching. The development of advanced dry etching tools and processes, have allowed the sub-micron images, in masking photoresist layers, to be transferred to underlying materials, such a silicon oxide, silicon nitride, and polysilicon, creating these materials, with sub-micron features, this resulting in smaller semiconductor chips, still possessing higher device densities.

The ability to use sub-micron features, or micro-miniaturization, has allowed performance improvements to be realized by the reduction of resistance and parasitic capacitance, resulting from the use of smaller features. In addition, the use of sub-micron features, results in smaller silicon chips with increased circuit densities, thus allowing more silicon chips to be obtained from a starting silicon substrate, thus reducing the cost of an individual silicon chip.

The performance speed of these devices is improved over its predecessors, but a resistance-capacitance delay and characteristics of lines are degraded due to the micro-miniaturization of the lines with the increased integration and with the increased length of the lines. Accordingly, a technique of forming a contact hole in the devices using sub-half micron design rules is important, particularly with respect to the desired goals of low resistance and high reliability of the semiconductor devices.

Additionally, as the step height of topography is too large for the ultra large-scale semiconductor device, the contact of the periphery circuit is widely used. As shown in FIGS. 1 and 2, a plurality of contact holes is formed in the semiconductor device mentioned above. The silicon substrate 2 is provided for the semiconductor device mentioned above and has a plurality of isolation regions 4 and a plurality of semiconductor devices 8 formed thereon, comprising array region 6 and periphery region. The semiconductor devices are formed of gate structures, dielectric spacers, and active regions. A first dielectric layer 10 and a second dielectric layer 12 are subsequently deposited on the semiconductor substrate for isolation and planarization. However, the step height of topography is still large.

Subsequently, to form the contact structures 16, a photoresist layer 14 is patterned on the second dielectric layer 12. When conventional etching process is used to form the contact holes, it tends to result in either etch-stop or polymer-redeposit phenomena 20 on the dielectric layer 10, especially a silicon oxide layer. As shown in FIG. 2, the plurality of contact holes 16 is formed in the first dielectric and second dielectric layers 10 and 12. As mentioned above, when etching the second dielectric layer 12 and the first dielectric layer 10, the etch-stop or the polymer-redeposit phenomena 20 can be formed thereon. Thus the active regions are not exposed, thereby reducing the reliabilities of the contact holes.

Moreover, it also tends to over etch 18 the active regions or the silicon substrate when the conventional etching process is performed to form the contact holes to expose the active regions. The silicon loss 18 in the active region and the silicon substrate 2 can be serious. The cross sectional view of the semiconductor device processed with the etching step mentioned above is shown in FIG. 2, in which the semiconductor devices is failed because the reliabilities of contact holes of the semiconductor devices are low.

Because it is very difficult to use the conventional etching process to form the contact holes of different depth, the yield of the semiconductor device of high integration is low. As the integrity of a semiconductor device getting higher, the reliability of contact is more important, and the etching step is becoming more critical. Therefore, it is a need to providing a method of improving contact reliability of the semiconductor device.

### SUMMARY OF THE INVENTION

It is an object of this invention to form a contact hole to an active device region of a metal oxide semiconductor field effect transistor (MOSFET) device.

It is another object of this invention to form a contact hole with improved contact reliability by multiple-step etching process exactly control main etching of the contact holes without unwanted overetch or etch-stop phenomena.

It is still another object of this invention to use a stop layer, allowing a first selective reactive ion etching (RIE) procedure to create the contact holes in a thick ILD layer, exposing the underlying etching stop layer, then using another selective RIE procedure to complete the contact holes.

In accordance with the present invention a method of improving contact reliability in the semiconductor device is described. A semiconductor substrate is provided having a plurality of semiconductor devices and a plurality of isolation regions formed thereon. An undoped silicon oxide layer is formed on the plurality of semiconductor devices, the plurality of isolation regions, and the semiconductor substrate. An etching stop layer, comprised of silicon nitride or silicon oxynitride, is formed on the undoped silicon oxide layer. The etching stop layer is also serve as a diffusion barrier. An interlevel dielectric layer, such as BPSG, is then deposited on the etching stop layer. A photoresist layer is pattern on the interlevel dielectric layer to define contact regions. A first etching process, such as selective RIE procedure, is performed to create a plurality of contact holes in the interlevel dielectric layer until exposing portions of the etching stop layer. A second etching process is performed to create the plurality of contact holes through the etching stop layer. A third etching process is then performed to create the plurality of contact holes through the silicon oxide layer, exposing portions of the active regions of the plurality of semiconductor devices. The pattern photoresist layer is removed.

### BRIEF DESCRIPTION OF THE DRAWINGS

The above features of the present invention will be more clearly understood from consideration of the following descriptions in connection with accompanying drawings in which:

FIG. 1 illustrates a cross sectional view of forming a dielectric layer on semiconductor substrate according to a conventional process;

FIG. 2 illustrates the cross sectional view of forming contact holes on the semiconductor substrate by an etching step according to the conventional process;

FIG. 3 illustrates a cross sectional view of forming an etching stop layer on a silicon oxide layer of the semiconductor substrate according to preferred embodiments of the present invention;

FIG. 4 illustrates a cross sectional view of forming a isolation dielectric layer on the etching stop layer of the semiconductor substrate according to preferred embodiments of the present invention;

FIG. 5 illustrates a cross sectional view of performing a first etching step to create a plurality of contact holes to expose portions of the etching stop layer on the semiconductor substrate according to preferred embodiments of the present invention;

FIG. 6 illustrates a cross sectional view of performing a second etching step to create a plurality of contact holes through the etching stop layer on the semiconductor substrate according to preferred embodiments of the present invention; and

FIG. 7 illustrates a cross sectional view of performing a third etching step to create a plurality of contact holes on the semiconductor substrate according to preferred embodiments of the present invention.

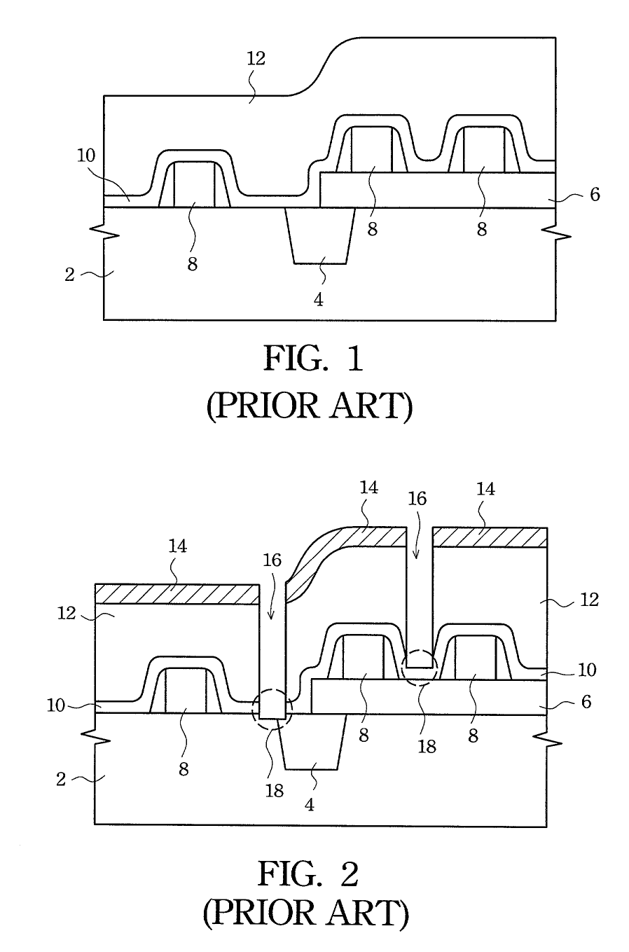

### DESCRIPTION OF THE PREFERRED EMBODIMENT

The method of improving contact reliability, in a composite insulator layer, exposing portions of active regions, and where the composite insulator layer is comprised an etching stop layer during etching procedure of contact holes, will now be described in detail.

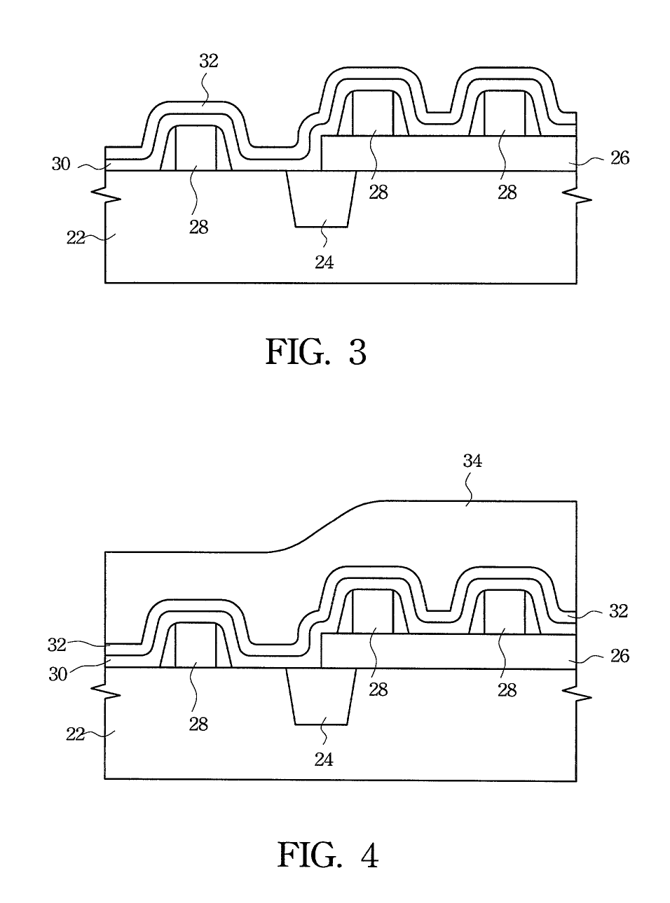

A single crystalline semiconductor substrate 22 is used and shown schematically in FIG. 3. An isolation region 24, can be comprised of either a silicon oxide filled, shallow trench region, or a thermally grown, silicon dioxide, field oxide region, is next formed in a region of semiconductor substrate 22. A pad dielectric layer 26 is thermally grown or deposited by high density plasma CVD (HDP-CVD), at a thickness between about 7000 to 9000 Angstroms. A plurality of semiconductor devices 28, comprised of a gate structure, dielectric spacers, active regions, and capacitor etc., is formed by conventional processes, such as deposition, etching, ion implantation, and photolithography etc. After formation of semiconductor devices, an insulator layer 30, such as undoped silicon oxide (USG) layer, is next deposited via LPCVD or plasma enhanced chemical vapor deposition (PECVD), at a thickness between about 500 to 1500 Angstroms.

A critical feature of this invention, the deposition of a thin insulator layer 32, to be used as an etching stop layer, during subsequent contact structures, is next addressed. A silicon nitride or a silicon oxynitride layer, is used as the thin, insulator etching stop layer. Silicon oxynitride layer 32, will offer the etch rate selectivity needed during a RIE procedure, used for the subsequent contact structures, and of upmost importance, can be serve as a diffusion barrier to improving the reliability issues of the semiconductor devices. Silicon oxynitride layer 32, shown schematically in FIG. 3, is deposited via chemical vapor deposition, such as LPCVD or PECVD, at a temperature between about 300 to 450° C., to a thickness between about 100 to 700 Angstroms.

Similarly, silicon nitride layer 32 is deposited via low pressure chemical vapor deposition to a thickness between about 300 to 700 Angstroms.

An interlevel dielectric (ILD) layer 34, comprised of silicon oxide, is next deposited via PECVD or LPCVD procedures on the etching stop layer 32, to a thickness between about 11000 to 16000 Angstroms. The ILD layer 34, shown schematically in FIG. 4, can also be comprised of borophosphosilicate glass (BPSG). The ILD layer 34 is flowed at a temperature between about 750 to 850° C. with furnace or rapid thermal process (RTP). A chemical mechanical polishing procedure may be then employed for planarization purposes, resulting in a smooth top surface topography for the ILD layer 34, however, it is alternative in the present invention.

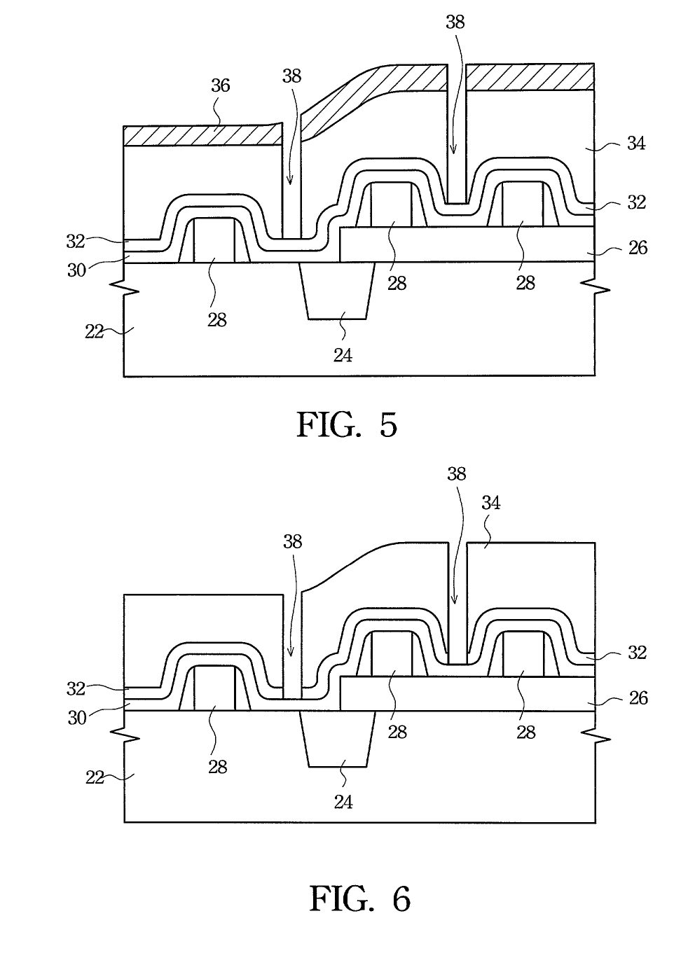

A photoresist layer 36 is formed on the ILD layer 34 and then pattern to define the subsequent contact structures to be formed in the ILD layer 34, the etching stop layer 32 and in the silicon oxide layer 30. A selective RIE procedure, using C₄F₈/CO as an etchant, is used to remove portions of the ILD layer 34, exposed in the pattern photoresist layer 36, shown schematically in FIG. 5. In a preferred embodiment, an etch rate ratio of the ILD layer 34 (BPSG) to silicon oxynitride 32 is about 200, allowing this first phase of the RIE procedure, the etching of ILD layer 34, to be monitored by the appearance of the silicon oxynitride layer 32. The depths of contact holes in the ILD layer 34 are different. The sizes of contact holes in array region and periphery region are also different. It tends to result in either the etch-stop or polymer redeposit in deep and small contact holes, and result in over-etch in shallow and large contact holes. However, the main etching of the ILD layer 34 to create the different depths and sizes contact holes can be initially controlled precisely according to the present invention.

A second RIE phase, using CH₃F/O₂ as an etchant, is then used to selectively remove exposed regions of the silicon oxynitride layer 32, resulting in contact holes 38, shown schematically in FIG. 6. In a preferred embodiment, an etch rate ratio of the silicon oxynitride 32 to the undoped silicon oxide layer 30 is about 10-20, allowing this second phase of the RIE procedure, the etching of etching stop layer 32, to be monitored by the appearance of the undoped silicon oxide layer 30. The endpoint for the second phase of RIE procedure can be initially controlled precisely.

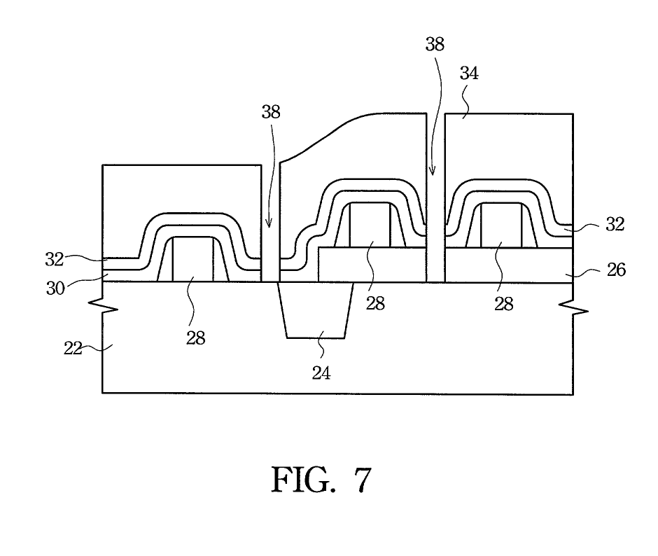

A third RIE phase, using CHF₃ as an etchant, is then used to selectively remove exposed regions of the undoped silicon oxide layer 30 and the pad dielectric layer 26, resulting in contact holes 38, shown schematically in FIG. 7. In a preferred embodiment, an etch rate ratio of the silicon oxide layer 30 to the silicon substrate 22 is about 200, allowing this third phase of the RIE procedure, the etching of silicon oxide layer 30, to be monitored by the appearance of the silicon substrate 22. The endpoint for the third phase of RIE procedure can be initially controlled precisely. The three-step etching process of the present invention is performed via the etch stop characteristics of silicon oxynitride layer 32 allowed contact holes 38 to be successfully formed without unwanted etch-stop of silicon oxide layer or overetch of the underlying active regions. Therefore, the contact reliability of the semiconductor devices can be apparently improved.

After removal of the pattern photoresist layer 36, used to define contact holes 38, via plasma oxygen ashing and careful wet cleans, a conductive layer (not shown) is deposited, completely filling contact holes 38. The conductive layer can be comprised of tungsten, aluminum, copper, or polysilicon. Regions of the conductive layer, residing on the top surface of the ILD layer 34, are then removed via a chemical mechanical polishing procedure, or via a selective RIE procedure to complete the contact structures.

As is understood by a person skilled in the art, the foregoing description of the preferred embodiment of the present invention is an illustration of the present invention rather than a limitation thereon. It is intended to cover various modifications and similar arrangements included within the spirit and scope of the appended claims.

The scope of the claims should be accorded to the broadest interpretation so as to encompass all such modifications and similar structures. While the preferred embodiment of the invention has been illustrated and described, it will be appreciated that various changes can be made therein without departing from the spirit and scope of the invention.

What is claimed is:

1. A method for improving contact reliability in semiconductor devices, said method comprising:
providing a semiconductor substrate having a plurality of device structures and a plurality of isolation regions formed thereon;
forming a silicon oxide layer on said plurality of device structures, said plurality of isolation regions, and said semiconductor substrate;
forming an etching stop layer on said silicon oxide layer;
forming an interlevel dielectric layer on said etching stop layer;
forming a photoresist pattern on said interlevel dielectric layer to define a plurality of contact regions;
performing a first etching process to create a plurality of contact holes in said interlevel dielectric layer until exposing portions of said etching stop layer;
performing a second etching process to create said plurality of contact holes through said etching stop layer until exposing portions of said silicon oxide layer;
performing a third etching process to create said plurality of contact holes through said silicon oxide layer, exposing portions of said semiconductor substrate and portions of active region of said plurality of device structures; and
removing said photoresist pattern layer.

2. The method according to claim 1, wherein said plurality of isolation regions is a trench isolation structure.

3. The method according to claim 1, wherein said silicon oxide layer is an undoped silicon glass (USG).

4. The method according to claim 1, wherein said silicon oxide layer has a thickness of about 500 to 1500 Å.

5. The method according to claim 1, wherein said etching stop layer is a silicon nitride layer.

6. The method according to claim 1, wherein said etching stop layer is a silicon oxynitride layer.

7. The method according to claim 1, wherein said etching stop layer has a thickness of about 100 to 700 Å.

8. The method according to claim 1, wherein said etching stop layer is also serve as a diffusion barrier.

9. The method according to claim 1, wherein said interlevel dielectric layer is a BPSG layer.

10. The method according to claim 1, wherein a depth of said plurality of contact holes is different from each other.

11. The method according to claim 1, wherein said first etching process is selective Reactive Ion Etching (RIE).

12. The method according to claim 1, wherein said first etching process is performed using C₄F₈/CO as an etchant.

13. The method according to claim 1, wherein an etch rate ratio of said interlevel dielectric layer to said etching stop layer in said first etching process is about 200.

14. The method according to claim 1, wherein said second etching process is selective Reactive Ion Etching (RIE).

15. The method according to claim 1, wherein said second etching process is performed using CH₃F/O₂ as an etchant.

16. The method according to claim 1, wherein an etch rate ratio of said etching stop layer to said silicon oxide layer in said second etching process is about 10-20.

17. The method according to claim 1, wherein said third etching process is selective Reactive Ion Etching (RIE).

18. The method according to claim 1, wherein said third etching process is performed using CHF₃ as an etchant.

19. The method according to claim 1, wherein an etch rate ratio of said interlevel dielectric layer to said etching stop layer in said third etching process is about 150-200.

20. A method for forming a plurality of contact holes with different depths on a semiconductor substrate using multiple-step etching process, said semiconductor substrate having a plurality of device structures and a plurality of isolation regions formed thereon, said method comprising the steps of:
forming an undoped silicon oxide layer on said plurality of device structures, said plurality of isolation regions, and said semiconductor substrate;
forming an etching stop layer on said undoped silicon oxide layer;
forming a BPSG layer on said etching stop layer;
forming a photoresist pattern on said BPSG layer to define a plurality of contact regions;
performing a first etching process to etch through said BPSG layer to create a plurality of contact holes until exposing portions of said etching stop layer;
performing a second etching process to create said plurality of contact holes through said etching stop layer until exposing portions of said undoped silicon oxide layer;
performing a second etching process to create said plurality of contact holes through said undoped silicon oxide layer, exposing portions of said semiconductor substrate and portions of active region of said plurality of device structures; and
removing said photoresist pattern layer.

21. The method according to claim 20, wherein said undoped silicon oxide layer has a thickness of about 500 to 1500 Å.

22. The method according to claim 20, wherein said etching stop layer is a silicon nitride layer.

23. The method according to claim 20, wherein said etching stop layer is a silicon oxynitride layer.

24. The method according to claim 20, wherein said etching stop layer has a thickness of about 100 to 700 Å.

25. The method according to claim 20, wherein said etching stop layer is serve as a diffusion barrier.

26. The method according to claim 20, wherein said first etching process is performed using C₄F₈/CO as an etchant.

27. The method according to claim 20, wherein an etch rate ratio of said BPSG layer to said etching stop layer in said first etching process is about 200.

28. The method according to claim 20, wherein said second etching process is performed using CH₃F/O₂ as an etchant.

29. The method according to claim 20, wherein an etch rate ratio of said etching stop layer to said undoped silicon oxide layer in said second etching process is about 10-20.

30. The method according to claim 20, wherein said third etching process is performed using CHF₃ as an etchant.

31. The method according to claim 20, wherein an etch rate ratio of said undoped silicon oxide layer to said semiconductor substrate in said third etching process is about 200.
